(19) United States
(12) Patent Application Publication
(10) Pub. No.: US 2025/0275166 A1
(43) Pub. Date: Aug. 28, 2025

(54) SEMICONDUCTOR DEVICE AND METHOD OF FABRICATING A SEMICONDUCTOR DEVICE

(71) Applicant: TAIWAN SEMICONDUCTOR MANUFACTURING COMPANY LTD., HSINCHU (TW)

(72) Inventors: CHEN-LIANG CHU, HSIN-CHU CITY (TW); TA-CHUAN LIAO, TAICHUNG CITY (TW); TA-YUAN KUNG, NEW TAIPEI CITY (TW); MING-TA LEI, HSIN-CHU CITY (TW); CHAN-YU HUNG, TAINAN CITY (TW); CHIEN-CHIH CHOU, NEW TAIPEI CITY (TW); FEI-YUN CHEN, HSINCHU (TW); YU-CHANG JONG, HSINCHU CITY (TW)

(21) Appl. No.: 18/586,596

(22) Filed: Feb. 26, 2024

(51) Int. Cl. H01L 29/66; H01L 21/285; H01L 29/40; H01L 29/45; H01L 29/78

(52) U.S. Cl. CPC H10D 30/0281; H01L 21/28518; H10D 30/022; H10D 30/603; H10D 30/65; H10D 64/017; H10D 64/111; H10D 64/62

(57) ABSTRACT

A semiconductor device and a method of fabricating the same are provided. The method includes steps of forming a source region and a drain region in a substrate; forming a gate structure on the substrate, wherein the source region and the drain region are disposed on opposite sides of the gate structure and separated from the gate structure by a distance; depositing an inter-layer dielectric (ILD) layer over the substrate and the gate structure; forming a first trench in the ILD layer, wherein the first trench exposes a first portion of the gate structure and overlies an area between the gate structure and one of the source and drain regions from a top-view perspective; and depositing a first conductive material in the first trench to form a conductive plate, wherein the conductive plate is electrically connected to the gate structure.

### BACKGROUND

As semiconductor technologies evolve, metal oxide semiconductor (MOS) transistors are increasingly used in today's integrated circuits. The MOS transistors are voltage controlled devices. When a control voltage is applied to a gate of a MOS transistor, and the control voltage is greater than a threshold of the MOS transistor, a conductive channel is established between a drain and a source of the MOS transistor. As a result, a current flows between the drain and the source of the MOS transistor. In contrast, when the control voltage applied to the gate of the MOS transistor is less than the threshold of the MOS transistor, the MOS transistor is turned off accordingly.

MOS transistors are increasingly important due to growing demand for battery-operated portable devices, such as cell phones. Maximizing battery life requires minimizing current flow, ideally with no current flow, during an off state of the MOS transistor so as to minimize or eliminate unnecessary power consumption.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 a schematic top view of a semiconductor device, in accordance with some embodiments of the present disclosure.

FIG. 2 is a schematic cross-sectional view along a line A-A′ of the semiconductor device in FIG. 1.

FIG. 3 is a schematic cross-sectional view along a line B-B′ of the semiconductor device in FIG. 1.

FIG. 4 a schematic top view of a semiconductor device, in accordance with some embodiments of the present disclosure.

FIG. 5 is a schematic cross-sectional view along a line C-C′ of the semiconductor device in FIG. 4.

FIG. 6 is a schematic cross-sectional view along a line D-D′ of the semiconductor device in FIG. 4.

FIG. 7 is a flowchart of a method of manufacturing a semiconductor device in accordance with some embodiments of the present disclosure.

FIGS. 8 to 12 are cross-sectional views of intermediate stages of the method of manufacturing a semiconductor device, in accordance with some embodiments of the present disclosure.

FIG. 13 is a top view of an intermediate stage of the method of manufacturing a semiconductor device, in accordance with some embodiments of the present disclosure.

FIG. 14 is a schematic cross-sectional view along a line E-E′ of the semiconductor device in FIG. 13.

FIGS. 15 to 20 are cross-sectional views of intermediate stages of the method of manufacturing a semiconductor device, in accordance with some embodiments of the present disclosure.

FIG. 21 is a top view of an intermediate stage of the method of manufacturing a semiconductor device, in accordance with some embodiments of the present disclosure.

FIG. 22 is a schematic cross-sectional view along a line F-F′ of the semiconductor device in FIG. 21.

FIG. 23 is a schematic cross-sectional view along a line G-G′ of the semiconductor device in FIG. 21.

FIG. 24 is a top view of an intermediate stage of the method of manufacturing a semiconductor device, in accordance with some embodiments of the present disclosure.

FIG. 25 is a schematic cross-sectional view along a line H-H′ of the semiconductor device in FIG. 24.

FIG. 26 is a schematic cross-sectional view along a line I-I′ of the semiconductor device in FIG. 24.

FIG. 27 is a top view of an intermediate stage of the method of manufacturing a semiconductor device, in accordance with some embodiments of the present disclosure.

FIG. 28 is a schematic cross-sectional view along a line J-J′ of the semiconductor device in FIG. 27.

FIGS. 29 to 33 are cross-sectional views of intermediate stages of the method of manufacturing a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

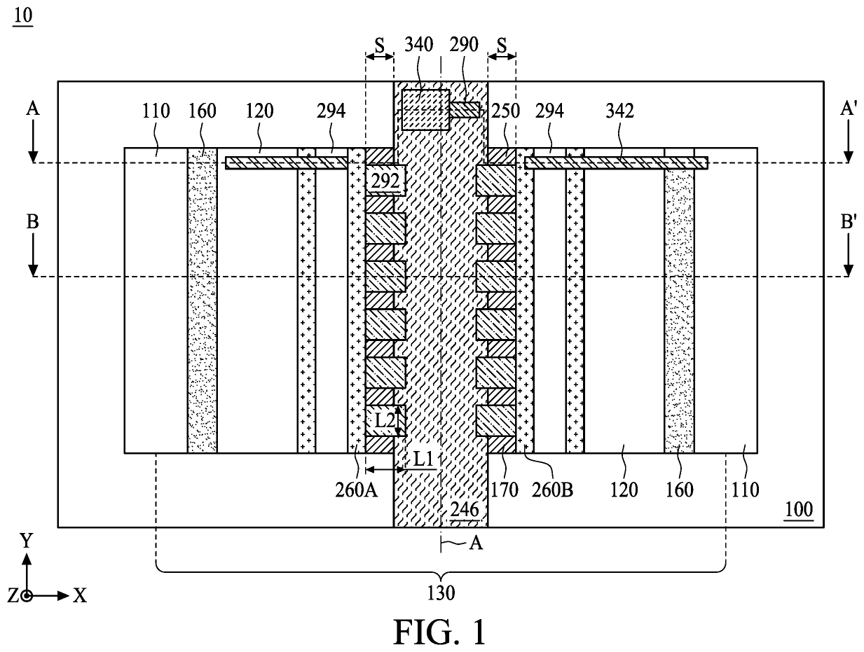

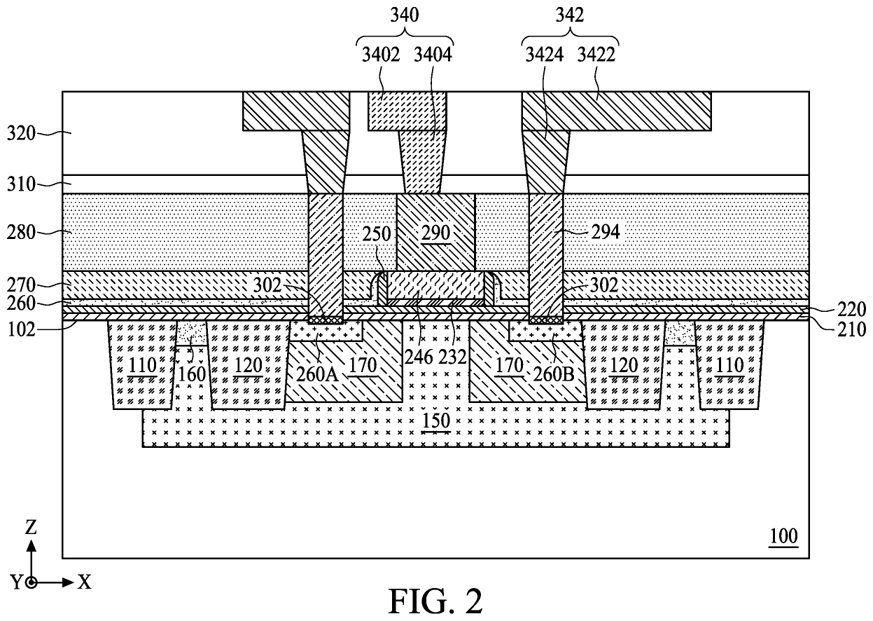

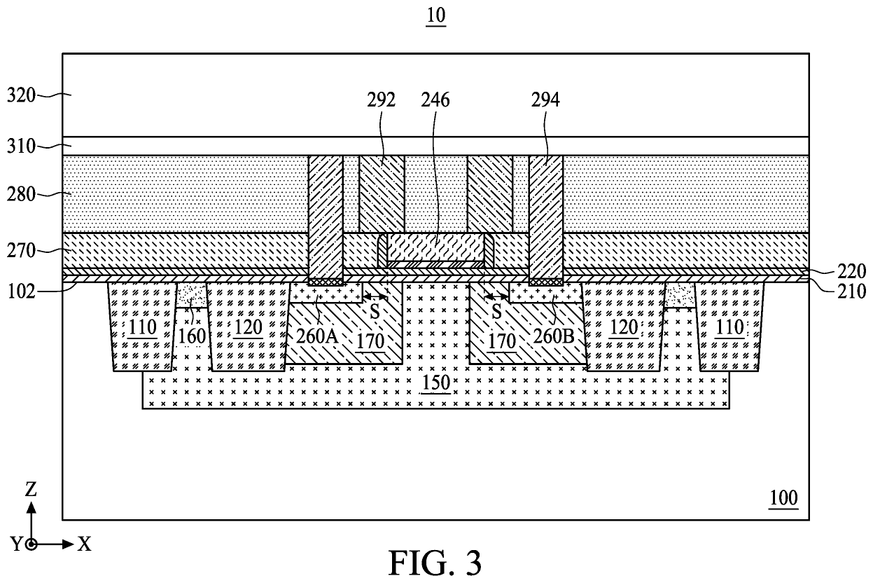

In accordance with some embodiments of the present disclosure, FIG. 1 is a schematic top view of a semiconductor device 10 in accordance with some embodiments of the present disclosure, FIG. 2 is a schematic cross-sectional view along a line A-A′ of the semiconductor device 10 in FIG. 1, and FIG. 3 is a schematic cross-sectional view along a line B-B′ of the semiconductor device 10 in FIG. 1. Referring to FIGS. 1 to 3, the semiconductor device 10 includes a substrate 100, a gate dielectric 232, a gate electrode 246, a source region 260A, a drain region 260B, a first conductive contact 290, a plurality of second conductive contacts 294, a plurality of conductive plates 292, a first interconnect structure 340, and a second interconnect structure 342.

The gate dielectric 232 and the gate electrode 246 are stacked on an upper surface 102 of the substrate 100. The gate dielectric 232 is sandwiched between the substrate 100 and the gate electrode 246. The gate electrode 246 may be a metal gate, although the gate electrode 246 may include polysilicon, metal silicide, or the like. The source region 260A and the drain region 260B are disposed in the substrate 100 and on opposite sides of the gate electrode 246. In some embodiments, the source region 260A is separated from the gate electrode 246 by a distance S from a top-view perspective. Similarly, the drain region 260B is separated from the gate electrode 246 by the distance S from the top-view perspective.

The first conductive contact 290 is disposed on the gate electrode 246. In some embodiments, the first conductive contact 290 is physically and electrically connected to the gate electrode 246. The first interconnect structure 340 is disposed over the first conductive contact 290. In some embodiments, the first interconnect structure 340 is physically and electrically connected to the first conductive contact 290. The first interconnect structure 340 may include a first metal line 3402 and a first via 3404; the first via 3404 is between the first conductive contact 290 and the first metal line 3402. The first via 3404 connects the first metal line 3402 to the first conductive contact 290. In some embodiments, the first interconnect structure 340 includes a plurality of first vias 3404 and a plurality of first metal lines 3402 stacked in an alternating manner to electrically connect the first conductive contact 290 to an external circuitry.

Each of the second conductive contacts 294 is disposed on the source region 260A or the drain region 260B. The first conductive contacts 290 and the second conductive contacts 294 may comprise same or different materials. For example, both the first conductive contacts 290 and the second conductive contacts 294 may include tungsten, copper, silver, titanium, polysilicon, or another suitable conductive material. In some embodiments, a silicide layer 302 is optionally interposed between one of the second conductive contacts 294 and the source region 260A and between another of the second conductive contacts 294 and the drain region 260B. The silicide layer 302 acts as an ohmic contact layer to reduce a contact resistance between the source region 260A or the drain region 260B and the respective second conductive contact 294.

The second interconnect structure 342 is disposed over the second conductive contacts 294. The second interconnect structure 342 may include one or more second metal lines 3422 and one or more second vias 3424 connecting the second metal line 3422 to the second conductive contact 294. In some embodiments, the first interconnect structure 340 and the second interconnect structure 342 may be simultaneously formed or formed using a same process.

The conductive plates 292 are disposed over the gate electrode 246. In some embodiments, each conductive plate 292 is physically and electrically connected to the gate electrode 246 and extends toward the source region 260A or the drain region 260B. For example, each conductive plate 292 extends to an area between the gate electrode 246 and the source region 260A or the drain region 260B from the top-view perspective. The individual conductive plates 292 may have substantially same sizes and shapes. In some embodiments, electricity applied to the semiconductor device 10 from the first interconnect structure 340 is conducted to the conductive plates 292 through the first conductive contact 290 and the gate electrode 246.

Referring to FIG. 1, each conductive plate 292 has a first length L1 in the X-direction and a second length L2 in the Y-direction orthogonal to the X-direction. In some embodiments, the first length L1 is greater than the second length L2. In some embodiments, the conductive plates 292 is evenly spaced in the Y-direction. The conductive plates 292 may be arranged with equal spacing between adjacent pairs along the Y-direction. In some embodiments, the conductive plates 292 are symmetric about a central axis A of the gate electrode 246, wherein the central axis A extends in the Y-direction.

In some embodiments, the semiconductor device 10 further includes a first inter-layer dielectric (ILD) layer 270, a second ILD layer 280, an isolation layer 310, and a low-k dielectric layer 320 disposed over the substrate 100. The gate electrode 246 may be laterally surrounded by the first ILD layer 270. The first conductive contact 290 and the conductive plates 292 are laterally surrounded by the second ILD layer 280. The first interconnect structure 340 and the second interconnect structure 342 penetrate the isolation layer 310 and the low-k dielectric layer 320. The first interconnect structure 340 in the isolation layer 310 and the low-k dielectric layer 320 may be formed using a dual-damascene method.

In some embodiments, the semiconductor device 10 further includes a first dielectric layer 210 and a second dielectric layer 220 disposed between the substrate 100 and the first ILD layer 270 and between the substrate 100 and the gate dielectric 232. The substrate 100 and the first dielectric layer 210 may include a same material, such as silicon.

In some embodiments, the first dielectric layer 210 includes material provided by the substrate 100. For example, the first dielectric layer 210 is a native oxide layer on the substrate 100. The second dielectric layer 220 is deposited on the first dielectric layer 210. Compared to first dielectric layer 210, the second dielectric layer 220 may provide a higher thermal budget during fabrication of the semiconductor device 10. The second conductive contacts 294 penetrate the first dielectric layer 210, the second dielectric layer 220, the first ILD layer 270, and the second ILD layer 280.

The semiconductor device 10 may further include spacer structures 250 and an etch stop layer 260. In some embodiments, the spacer structures 250 are disposed on opposite sidewalls of the gate electric 232 and the gate electrode 246. The etch stop layer 260 may be disposed between the second dielectric layer 220 and the first ILD layer 270 and between the spacer structures 250 and the first ILD layer 270.

The semiconductor device 10 may further include a plurality of first isolation structures 110, a plurality of second isolation structures 120, a well region 150, one or more guard regions 160, and a pair of lightly-doped regions 170 disposed in the substrate 100. The first isolation structures 110 and the second isolation structures 120 may be shallow trench isolation (STI) structures. The first isolation structures 110 are used to define an active region 130 in and above which the semiconductor device 10 is formed. The second isolation structures 120 are disposed in the active region 130 and used to define a device region 140 in and above which the gate electrode 246, the source region 260A, and the drain region 260B are formed.

The well region 150 is disposed in the active region 130 and may have a first conductivity type. The guard regions 160 may extend along two sides of the device region 140. In some embodiments, each guard region 160 is disposed between one of the first isolation structures 110 and adjacent second isolation structure 120. In alternate embodiments, the guard region 160 may form a ring encircling (from the top-view perspective of the substrate 100) the device region 140 with the gate electrode 246, the source region 260A and the drain region 260B therein. The guard regions 160 have the first conductivity type. In some embodiments, the guard regions 160 have an impurity concentration greater than that of the well region 150.

The lightly-doped regions 170 are disposed in the device region 140 and spaced apart from each other in the X-direction. The lightly-doped regions 170 have a second conductivity type different from the first conductivity type. The lightly-doped regions 170 may be connected to the second isolation structures 120, and the source region 260A and the drain region 260B are disposed at upper portions of the lightly-doped regions 170. The source region 260A and the drain region 260B may have the second conductivity type. In some embodiments, in an n-type semiconductor device 10, the first conductivity type is a p-type and the second conductivity type is an n-type. Alternatively, in a p-type semiconductor device 10, the first conductivity type is the n-type and the second conductivity type is the p-type.

In some embodiments, the semiconductor device 10 is a metal-oxide semiconductor (MOS) transistor for medium voltage (MV) applications such as a source driver of a liquid-crystal display (LCD) monitor. The semiconductor device 10 may have an operating voltage of about 6 to 10 volts. Referring to FIGS. 1 to 3, the distance S between the source region 260A or the drain region 260B and the gate electrode 246 is reduced by reducing a length, in the X-direction, of the gate electrode 246 while maintaining a desired channel length between the source region 260A and the drain region 260B.

With the reduction in the length of the gate electrode 246, current caused by gate-induced drain leakage (GIDL) effect can be reduced during an off state of the semiconductor device 10. However, a distribution of the highest electrical field is therefore moved from near the upper surface 102 of the substrate 100 to somewhere deeper in the semiconductor substrate 100. Such a change in the distribution of the electrical field (along a channel region of the semiconductor device 10) results in an increase of a substrate current during an on state of the semiconductor device 10, which may cause power consumption performance to deteriorate during operation of the semiconductor device 10.

To address the abovementioned issue, in the present disclosure, in order to rearrange distribution of the electrical field during the on state of the semiconductor device 10, the conductive plates 292 are arranged in direct contact with the gate electrode 246 and extend to overlap some areas between the gate electrode 246 and the source region 260A and between the gate electrode 246 and the drain region 260B. For example, the distribution of the highest electrical field can be moved back to a position nearer to the upper surface 102 of the substrate 100 as compared to configurations in which the conductive plates 292 are absent. As a result, a substrate current during the on state is reduced.

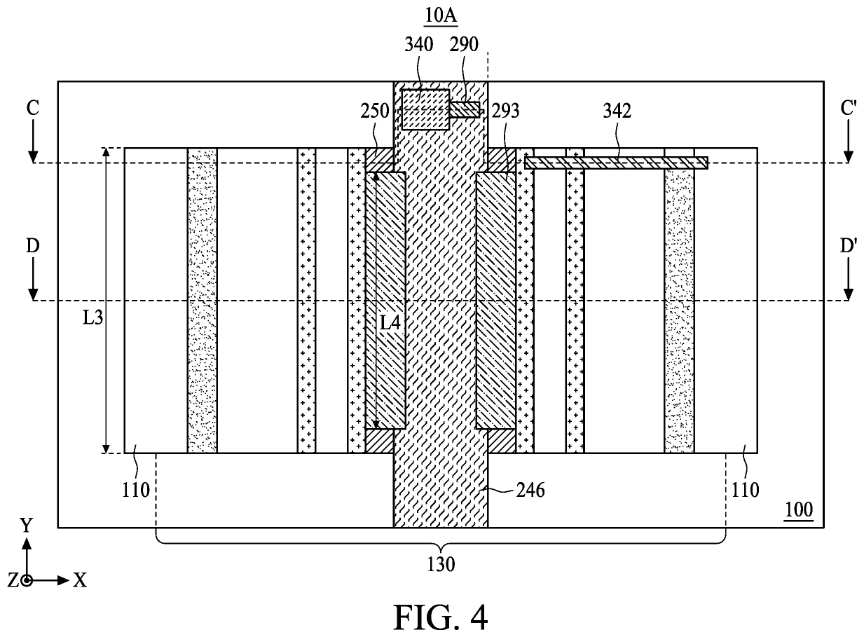

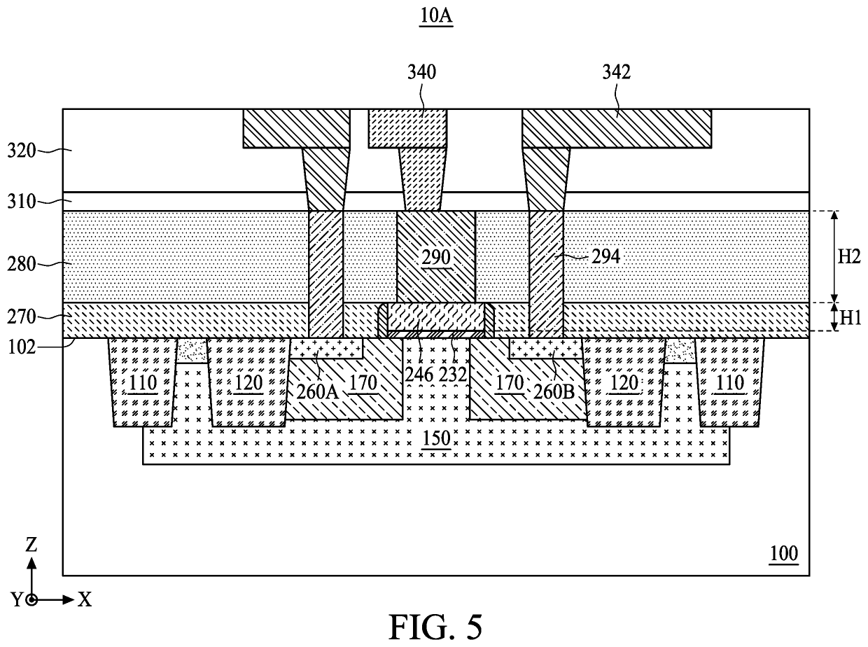

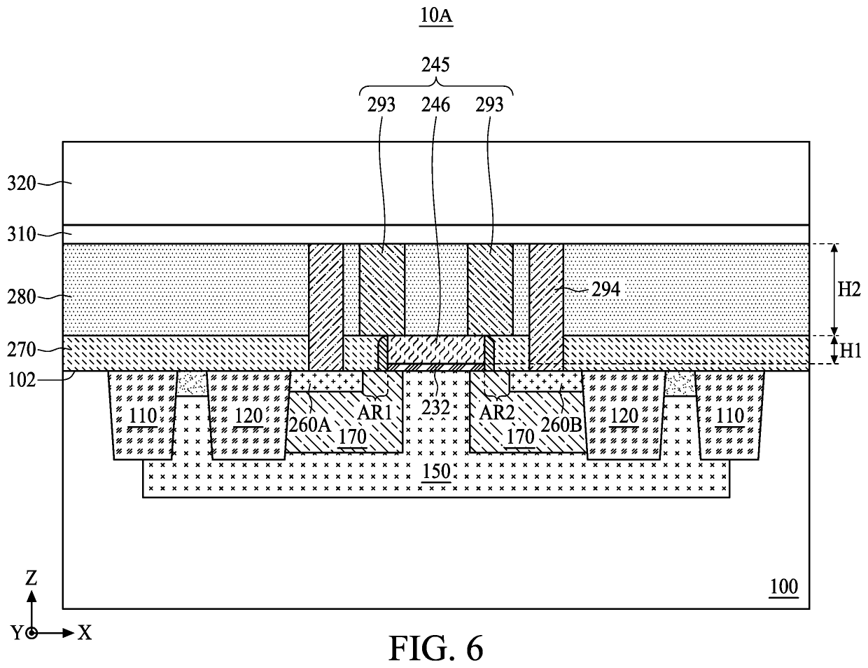

In accordance with some embodiments of the present disclosure, FIG. 4 is a schematic top view of a semiconductor device 10A, FIG. 5 is a schematic cross-sectional view along a line C-C′ of the semiconductor device 10A in FIG. 4, and FIG. 6 is a schematic cross-sectional view along a line D-D′ of the semiconductor device 10A in FIG. 4. Referring to FIGS. 4 to 6, the semiconductor device 10A includes a substrate 100, a gate dielectric 232, a gate structure 245, a source region 260A, a drain region 260B, a first ILD layer 270, a second ILD layer 280, a first conductive contact 290, a plurality of second conductive contacts 294, an isolation layer 310, a low-k dielectric layer 320, a first interconnect structure 340, and a second interconnect structure 342.

The gate dielectric 232 is disposed on an upper surface 102 of the substrate 100, and the gate structure 245 is disposed over the gate dielectric 232. The source region 260A and the drain region 260B are disposed in the substrate 100 and on opposite sides of the gate structure 245. In some embodiments, the gate structure 245 includes a gate electrode 246 and a pair of conductive plates 293 disposed over the gate electrode 246. The gate electrode 246 is disposed on the gate dielectric 232. The gate dielectric 232 and the gate electrode 246 may be laterally surrounded by the first ILD layer 270.

The conductive plates 293 are spaced apart from one another along the X-direction and connected to the gate electrode 246. Each conductive plate 293 overlaps a portion of the gate electrode 246 and a portion of the first ILD layer 270. In some embodiments, one of the conductive plates 293 overlaps an area AR1 between the gate electrode 246 and the source region 260A, and another of the conductive plates 293 overlaps an area AR2 between the gate electrode 246 and the drain region 260B. The conductive plates 293 are laterally surrounded by the second ILD layer 280. In some embodiments, the gate electrode 246 has a first height H1, and the conductive plates 293 have a second height H2 greater than the first height H1.

Referring to FIG. 4, the substrate 100 includes an active area 130 defined by first isolation structures 110. The active area 130 has a third length L3 in the Y-direction, and the conductive plate 292 has a fourth length L4 in the Y-direction. In some embodiments, the fourth length L4 is less than the third length L3. The gate electrode 246 may extend across the third length L3 of the active area 130.

Referring to FIGS. 5 and 6, the gate electrode 246, the first conductive contact 290, and the first interconnect structure 340 are stacked along the Z-direction. In some embodiments, the first conductive contact 290 connects the first interconnect structure 340 to the gate electrode 246 and is laterally surrounded by the second ILD layer 280. The first conductive contact 290 may have the second height H2. In some embodiments, the first conductive contact 290 and the conductive plates 293 are simultaneously formed or formed using a same process.

The second conductive contacts 294 and the second interconnect structure 342 may be stacked in the Z-direction. In some embodiments, each second conductive contact 294 connects the second interconnect structure 342 to the source region 260A or to the drain region 260B. The second conductive contacts 294 are electrically isolated from the first conductive contacts 290 and the conductive plates 293 by the first and second ILD layers 270 and 280. The first and second interconnect structures 340 and 342 are surrounded by the isolation layer 310 and the low-k dielectric layer 320 disposed on the second ILD layer 280.

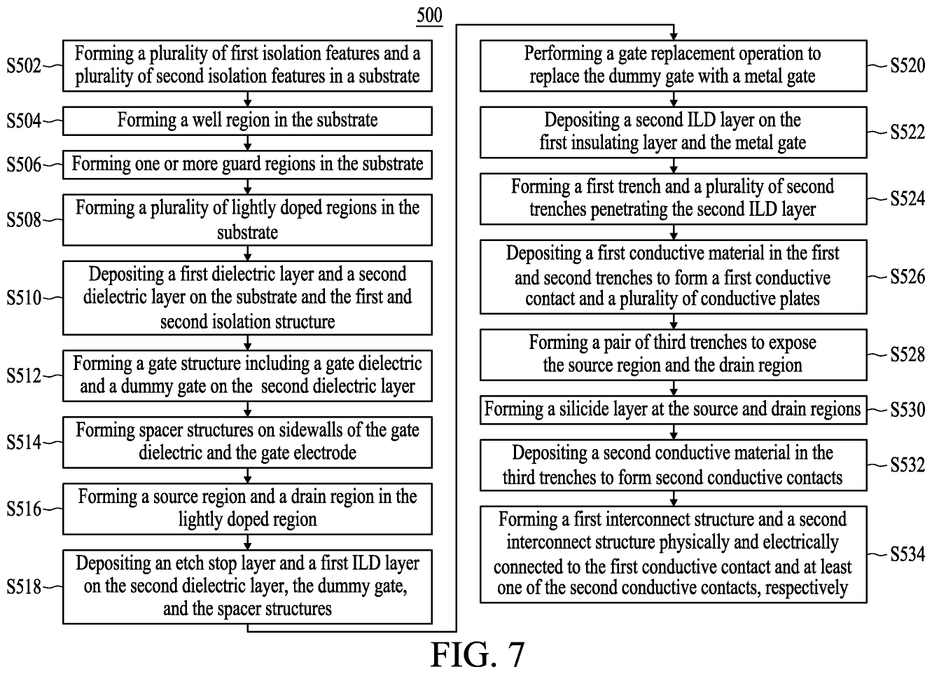

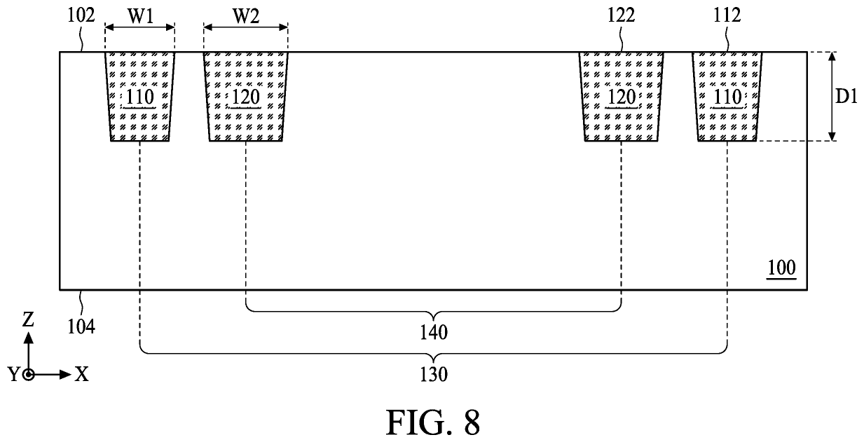

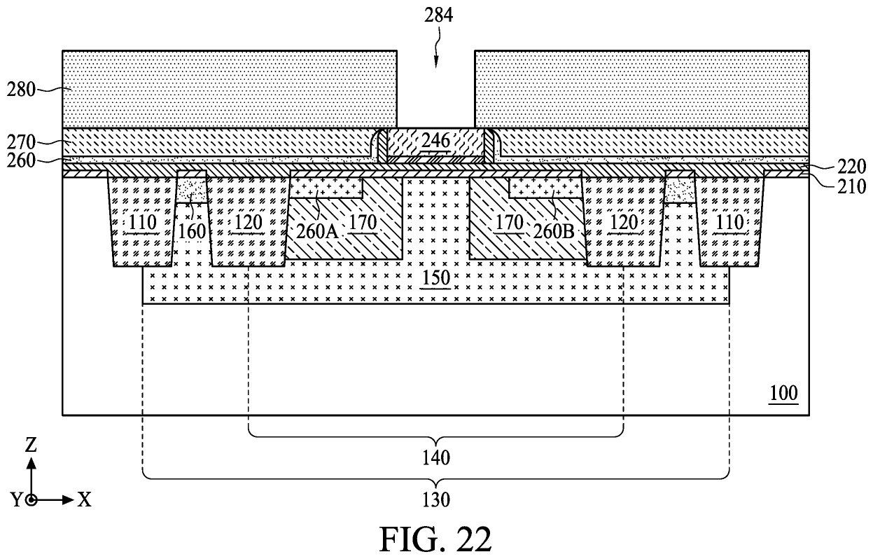

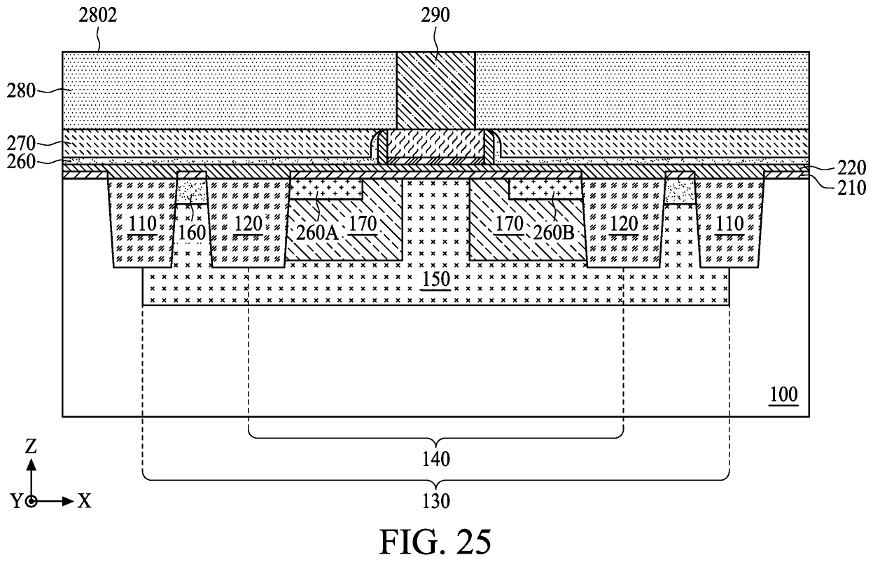

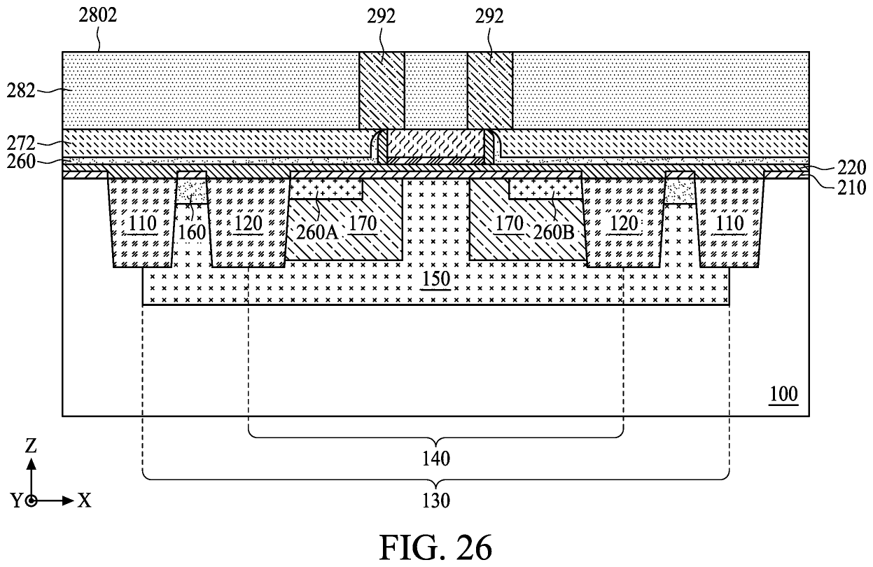

FIG. 7 is a flowchart of a method 500 of manufacturing a semiconductor device 10, in accordance with some embodiments of the present disclosure. FIGS. 8 to 33 are top views and cross-sectional views of intermediate stages of the method 500 of manufacturing the semiconductor device 10, in accordance with some embodiments of the present disclosure. In the following description, the manufacturing stages shown in FIGS. 8 to 33 are discussed with reference to the process steps shown in FIG. 7. It should be understood that additional steps can be provided before, during, and after the steps shown in FIG. 7, and some of the steps described below can be replaced or eliminated, for additional embodiments of the method 500. The order of the steps may be changed.

Referring to FIG. 8, a plurality of first isolation structures 110 and a plurality of second isolation structures 120 are formed in a substrate 100 in accordance with step S502 in FIG. 7. The substrate 100 has an upper surface 102 and a lower surface 104 opposite to the upper surface 102. The first isolation structures 110 and the second isolation structures 120 extend from the upper surface 102 for a first depth D1 in the Z direction. The substrate 100 may be a bulk semiconductor substrate or a semiconductor-on-insulator (SOI) substrate. The substrate 100 may include crystalline silicon, crystalline germanium, a compound semiconductor (such as silicon carbide, gallium arsenide, or gallium phosphide), an alloy semiconductor (such as silicon germanium or gallium arsenide phosphide), or a combination thereof.

The first isolation structures 110 are formed in the substrate 100 to define various active regions 130. The second isolation structures 120 may be located in the active region 130 and may be laterally offset from the first isolation structures 110 in the X-direction to define a device region 140. In some embodiments, the active region 130 extends from a center portion of one of the first isolation structures 110 to a center portion of another of the first isolation structures 110. The device region 140 may extend from a center portion of one of the second isolation structures 120 to a center portion of another of the second isolation structures 120. The first isolation structures 110 and the second isolation structures 120 may be formed by etching the substrate 100 to form trenches and filling the trenches with an insulating material using a deposition operation. In some embodiments, a polishing operation is performed to remove excess portions of the insulating material from the upper surface 102 of the substrate 100. The insulating material may include silicon oxide, silicon nitride, silicon oxynitride, fluoride-doped silicate (FSG), a low-k dielectric material, another suitable dielectric material, or a combination thereof.

In some embodiments, the first isolation structures 110 and the second isolation structures 120 have tapered profiles with their upper portions wider than their lower portions in a cross-sectional plane defined in the X-direction and Z-direction. Sizes of the first isolation structures 110 and the second isolation structures 120 may be substantially same or different. In some embodiments, the first isolation structures 110 have a first width W1 (e.g., an upper or maximum width), and the second isolation structures 120 have a second width W2 (e.g., an upper or maximum width) greater than the first width W1.

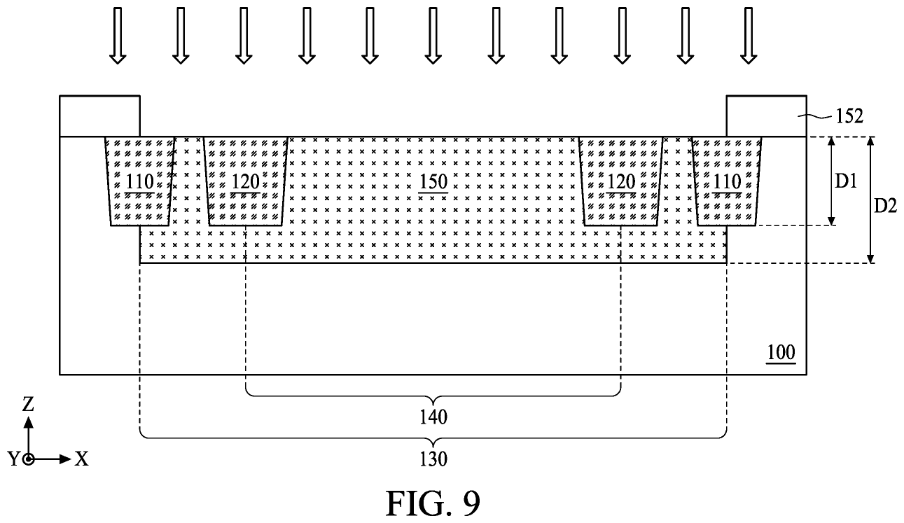

Referring to FIG. 9, a well region 150 is formed in the substrate 100 in accordance with step S504 in FIG. 7. The well region 150 is formed in the active region 130. In some embodiments, the well region 150 has a second depth D2 greater than the first depth D1 of the first and second isolation structures 110 and 120. The well region 150 is formed by implanting an impurity of a first conductivity type into the substrate 100 through a first patterned mask layer 152. After the well region 150 is formed, the first patterned mask layer 152 is removed, for example, in an ashing and/or wet strip operation.

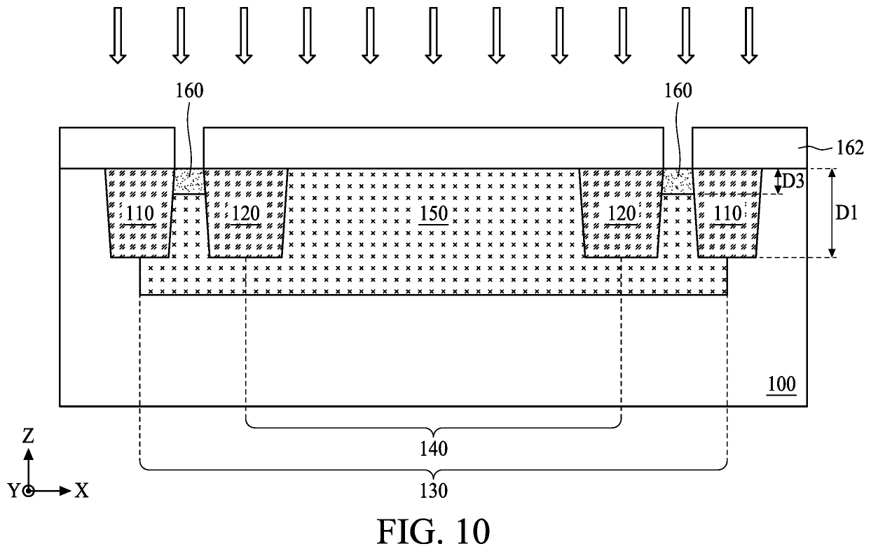

Referring to FIG. 10, one or more guard regions 160 are formed in the substrate 100 in accordance with step S506 in FIG. 7. The guard regions 160 may be disposed at an upper portion of the well region 150. In some embodiments, the guard regions 160 are between the first isolation structure 110 and an adjacent second isolation structure 120. The guard region 160 has a third depth D3 less than the first depth D1 of the first and second isolation structures 110 and 120. In some embodiments, the well region 150 has a first doped concentration, and the guard regions 160 have a second doped concentration greater than the first doped concentration. The guard region 160 is formed by implanting ions of an impurity of the first conductivity type into the substrate 100 through a second patterned mask layer 162. After the guard region 160 is formed, the second patterned mask layer 162 is removed, for example, in an ashing and/or wet strip operation.

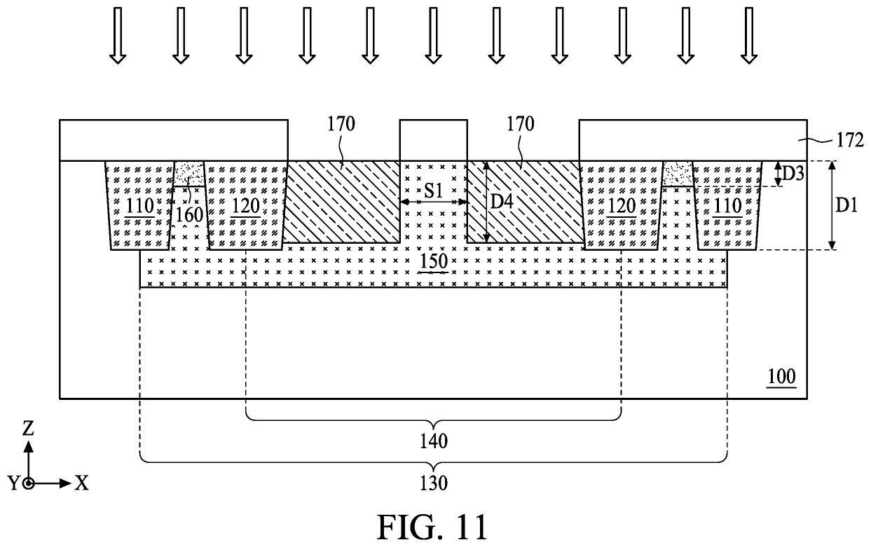

Referring to FIG. 11, a plurality of lightly-doped regions 170 are formed in the substrate 100 in accordance with step S508 in FIG. 7. The lightly-doped regions 170 are formed in the device region 140. In some embodiments, the lightly-doped regions 170 are separated from one another by a first distance S1 measured in the X-direction. The lightly-doped regions 170 have a fourth depth D4, which may be greater than the third depth D3 and less than the first depth D1. The lightly-doped regions 170 are formed by implanting ions of an impurity of a second conductivity type into the substrate 100 through a third patterned mask layer 172. The lightly-doped regions 170 may have a third doped concentration between the first and second doped concentrations. After the lightly-doped regions 170 are formed, the third patterned mask layer 172 is removed, for example, in an ashing and/or wet strip operation.

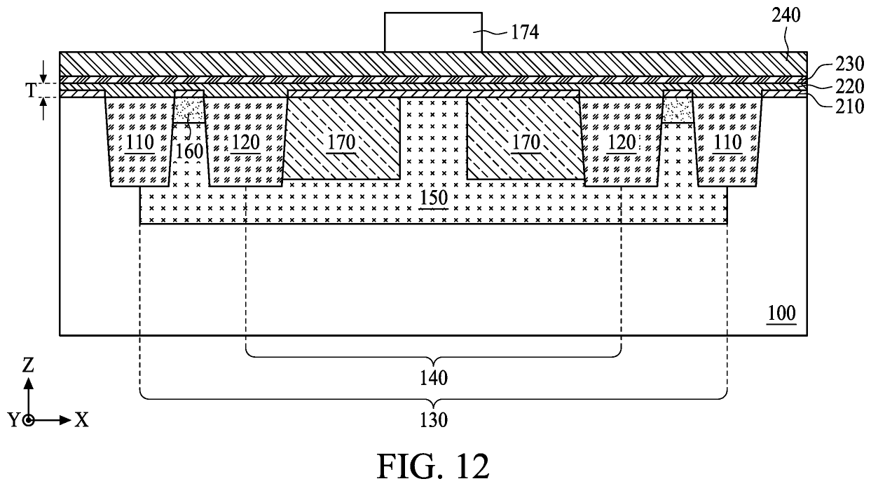

Referring to FIG. 12, a first dielectric layer 210 and a second dielectric layer 220 are subsequently formed on the substrate 100 in accordance with step S510 in FIG. 7. The first dielectric layer 210 and the second dielectric layer 220 may be formed of oxide layers using different deposition methods. In some embodiments, the first dielectric layer 210 is formed using a thermal oxidation operation, and the second dielectric layer 220 is formed using a high temperature deposition, such as a rapid thermal chemical vapor deposition. Thus, the first dielectric layer 210 and the second dielectric layer 220 have different film properties such as different thermal budgets and different etching rates with respect to a same etchant. In some embodiments, the thermal oxidation operation is used to grow a high-purity and highly-conformal silicon oxide (SiOₓ) such as silicon dioxide (SiO₂) on the substrate 100, and the high temperature deposition is used to deposit silicon oxide with a high deposition rate on the first dielectric layer 210, the first isolation structures 110, and the second isolation structures 120. In some embodiments, the first and second dielectric layers 210 and 220 have a combined thickness ranging from about 100 to about 300 angstroms. The first and second dielectric layers 210 and 220 may have a combined thickness of about 200 angstroms.

Still referring to FIG. 12, a third dielectric layer 230, a conductive layer 240, and a fourth patterned mask layer 174 are subsequently formed on the second dielectric layer 220. The third dielectric layer 230 may include a high-k material such as hafnium oxide (HfO₂) or other suitable material. The high-k dielectric material may have a dielectric constant greater than about 4. The third dielectric layer 230 is deposited to cover a substantially entire top surface of the second dielectric layer 220 using chemical vapor deposition (CVD) or other suitable methods.

The conductive layer 240 may be a polysilicon layer. The conductive layer 240 may be formed by any suitable technique, such as CVD, physical vapor deposition (PVD), atomic layer deposition (ALD), and/or other suitable methods. The fourth patterned mask layer 174 partially overlaps the well regions 150 and the lightly-doped regions 170. In some embodiments, the fourth patterned mask layer 174 extends continuously from over one of the well regions 150 to over another of the well regions 150 (not shown).

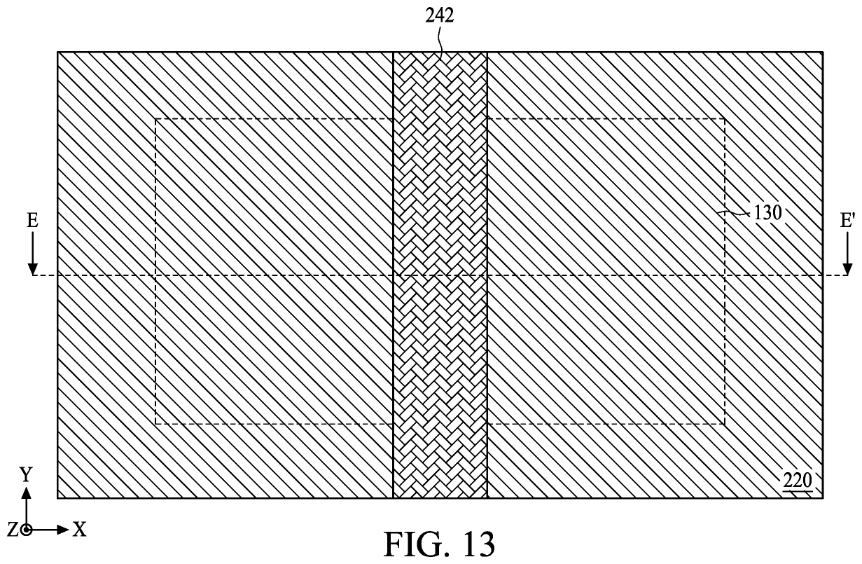

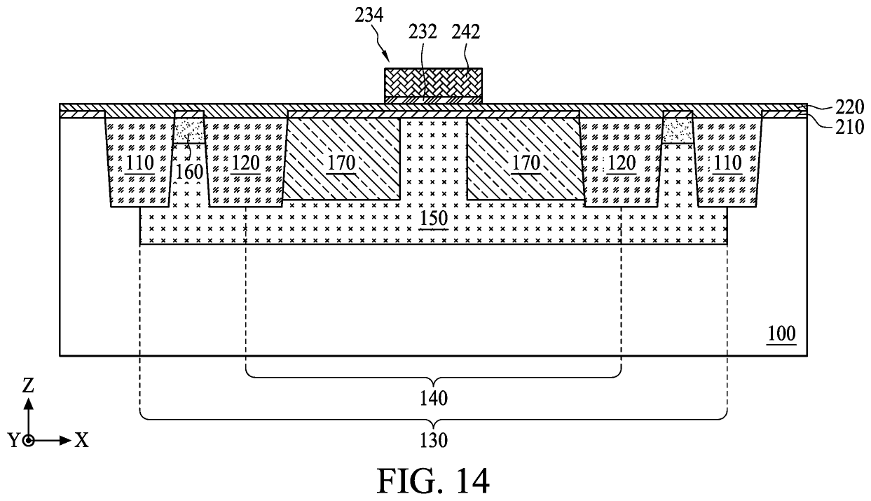

Referring to FIGS. 13 and 14, portions of the third dielectric layer 230 and the conductive layer 240 not protected by the fourth patterned mask layer 174 are removed. As a result, a gate structure 234 including a gate dielectric 232 and a dummy gate 242 is formed on the second dielectric layer 220 (step S512). The gate dielectric 232 and the dummy gate 242 extend in the Y-direction and across the active area 130. The removal of the portions of the conductive layer 240 and the third dielectric layer 230 may be implemented using an etching operation. After the etching process, the fourth patterned mask layer 174 is removed, for example, using an ashing process or a wet etching process.

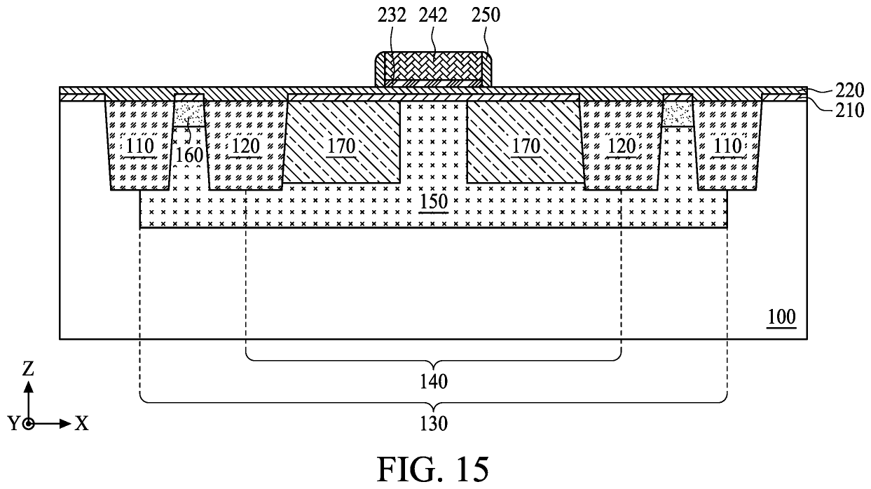

Referring to FIG. 15, spacer structures 250 are formed on sidewalls of the gate dielectric 232 and the dummy gate 242 in accordance with step S514 in FIG. 7. The formation of the spacer structures 250 may include blanket formation of a spacer layer (not shown) on the second dielectric layer 220, the gate dielectric 232, and the dummy gate 242, and then performing one or more anisotropic etching operations to remove horizontal portions of the spacer layer. Remaining vertical portions of the spacer layer form the spacer structures 250.

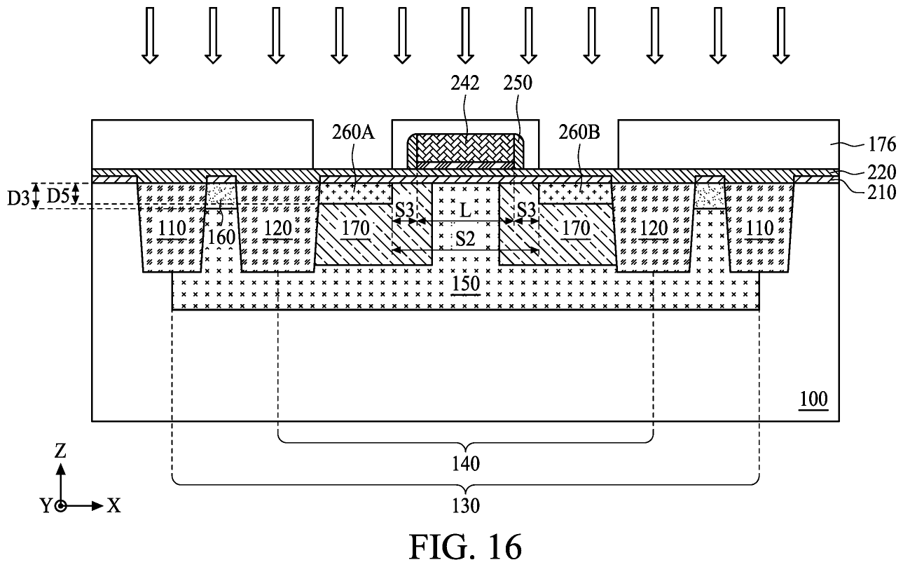

Referring to FIG. 16, a source region 260A and a drain region 260B are formed in the substrate 100 in accordance with step S516 in FIG. 7. The source region 260A and the drain region 260B are formed in the lightly-doped region 170. The source region 260A and the drain region 260B are spaced apart from one another by a second distance S2 measured in the X-direction. In some embodiments, the second distance S2 is greater than a length L of the gate dielectric 232 or the dummy gate 242 in the X-direction.

An edge of the source region 260A or the drain region 260B is offset from an edge of the dummy gate 242. In some embodiments, the source region 260A is separated from the gate dielectric 232 or the dummy gate 242 by a third distance S3. The drain region 260B is also separated from the gate dielectric 232 or the gate electrode 242 by the third distance S3. In some embodiments, the third distance S3 is in a range of about 40 nm to about 50 nm.

The source region 260A and the drain region 260B have a fifth depth D5 that is less than the third depth D3 of the guard region 160. The source region 260A and the drain region 260B are formed by implanting ions of an impurity of the second conductivity type into the substrate 100 through a fifth patterned mask layer 176. In some embodiments, the fifth patterned mask layer 176 covers the dummy gate 242 and the spacer structures 250. The source region 260A and the drain region 260B have a fourth doped concentration greater than the first doped concentration of the well regions 150.

In some embodiments, ions for the formation of the source and drain regions 260A and 260B are implanted with an implant energy between about 5 keV and about 8 keV, such as about 6 keV. The n-type source and drain regions 260A and 260B may be doped with, for example, phosphorus at a concentration of about 2×10¹⁵ atoms/cm². In some embodiments, ions for the formation of the source and drain regions 260A and 260B are implanted with an implant energy between about 2 keV and about 4 keV, such as about 3 keV when the second conductivity type is a p-type. The p-type source and drain regions 260A and 260B may be doped with, for example, boron at a concentration of about 6×10¹⁵ atoms/cm². After the source region 260A and the drain region 260B are formed, the fifth patterned mask layer 176 is removed, for example, in an ashing and/or wet strip operation.

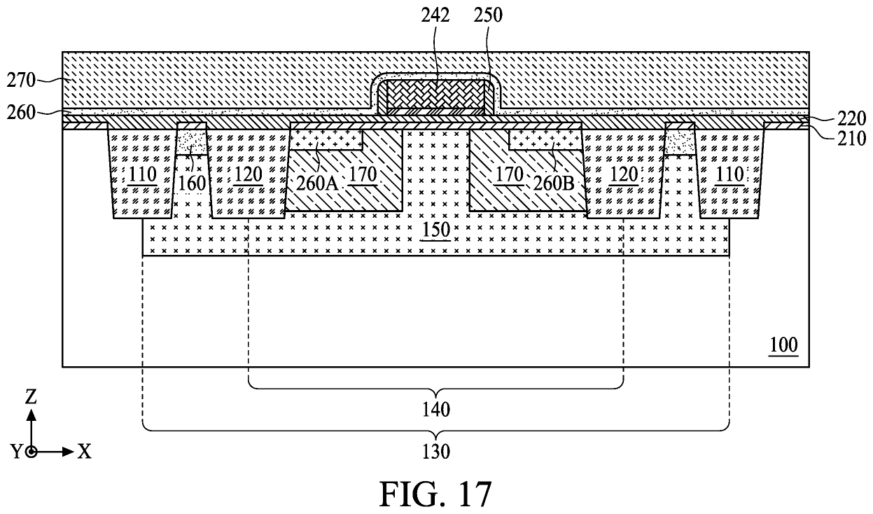

Referring to FIG. 17, an etch stop layer 260 and a first ILD layer 270 are deposited over the second dielectric layer 220, the dummy gate 242, and the spacer structures 250 in accordance with step S518 in FIG. 7. The etch stop layer 260, having a substantially uniform thickness, has a topography following topographies of the second dielectric layer 220, the dummy gate 242, and the spacer structures 250. In some embodiments, the etch stop layer 260 includes silicon nitride, silicon carbide (SiC), or other dielectric materials. The etch stop layer 260 may be formed by a suitable technique, such CVD, PVD, ALD, other suitable methods, and/or a combination thereof.

The first ILD layer 270 is formed over the etch stop layer 260. The first ILD layer 270 is blanketly formed to a height higher than a top surface of the dummy gate 242. The first ILD layer 270 may include material such as tetraethylorthosilicate (TEOS), undoped silicate glass, phosphosilicate glass (PSG), boron doped silicon glass (BSG), borophosphosilicate glass (BPSG), fused silica glass (FSG), and/or other suitable dielectric materials. The first ILD layer 270 is formed by CVD, spin coating, sputtering, or other suitable methods.

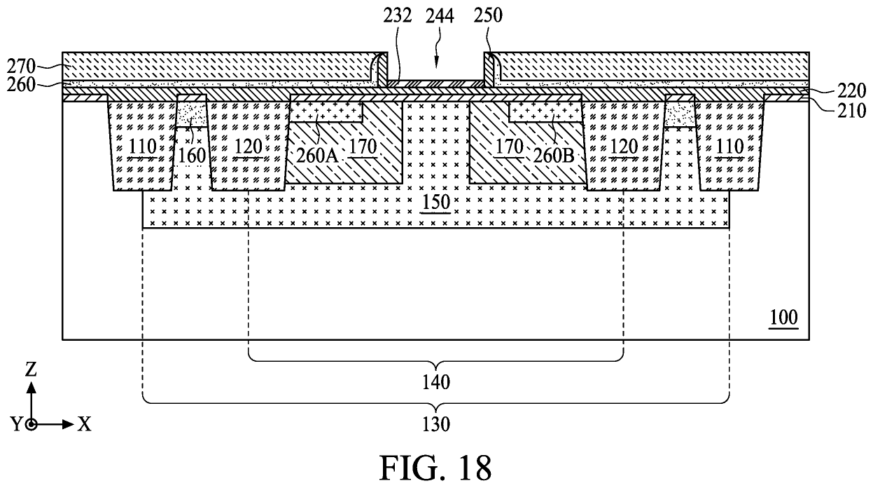

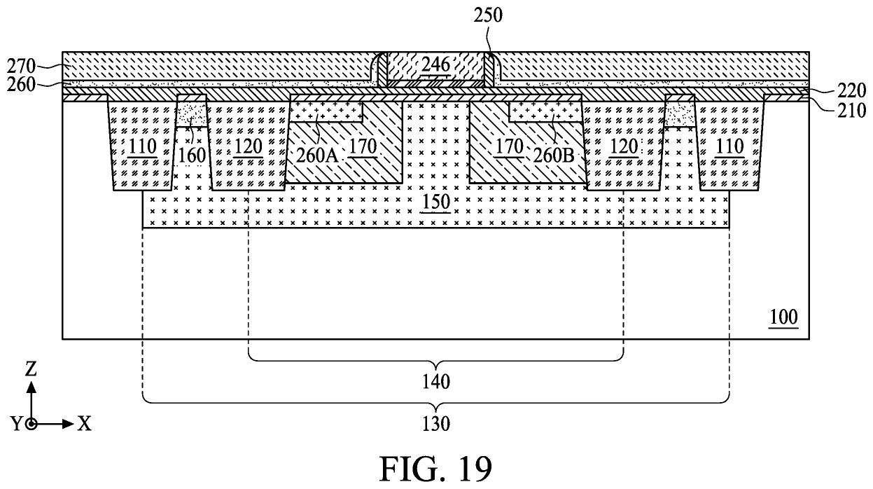

Referring to FIGS. 18 and 19, a replacement gate operation is performed in accordance with step S520 in FIG. 7. The replacement gate operation may include a planarization step, a removal step, and a deposition step. The planarization step is performed using, for example, a chemical mechanical polish (CMP) operation. The CMP operation is performed to remove excess portions of the first ILD layer 270 and the etch stop layer 260, wherein the excess portions are over the dummy gate 242. Accordingly, the dummy gate 242 is exposed.

In the removal step, the dummy gate 242 is removed to form a trench 244 with the spacer structures 250 as its sidewalls. The dummy gate 242 may be removed by a dry etch, a wet etch, or a combination thereof. In some embodiments, the dummy gate 242 is removed while the gate dielectric 232 is retained. In alternative embodiments, the dummy gate 242 and the gate dielectric 232 are removed during the removal step.

In the deposition step, the trench 244 is filled with one or more metal layers. The metal layers may include n-type work function metals (such as Ti, Ag, TaAl, TaAIC, TiAlN, TaC, TaCN, TaSiN, Mn, or Zr) and/or p-type work function metals (such as TiN, TaN, Ru, Mo, Al, WN, ZrSi₂, MoSi₂, TaSi₂, or NiSi₂). Other metal layers may also be formed in the trench 244, such as a glue layer, a diffusion barrier layer, a filling layer, or the like. The work function metal layer(s) or other metal layers may be deposited by CVD, PVD, electroplating and/or other suitable operations. After the deposition of the metal layers, a planarization process, e.g., CMP, is performed to planarize the metal layers to form a gate electrode 246 in the opening 244.

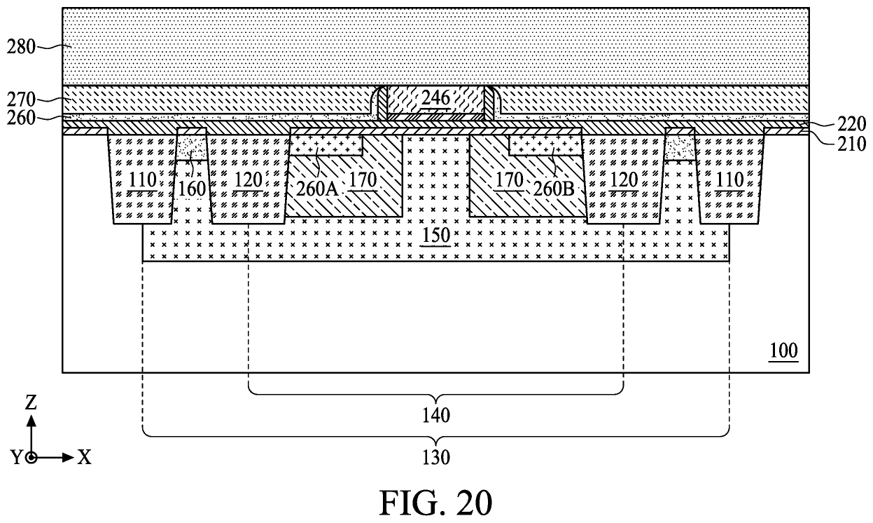

Referring to FIG. 20, a second ILD layer 280 is deposited on the gate electrode 246 and first ILD layer 270 in accordance with step S522 in FIG. 7. The first ILD layer 270 and the second ILD layer 280 may comprise same or different materials. The second ILD layer 280 may include oxide, material such as TEOS, undoped silicate glass, PSG, BSG, BPSG, FSG, and/or other suitable dielectric materials. The second ILD layer 280 is formed by CVD, spin coating, sputtering, or another suitable method. In some embodiments, the second ILD layer 280 may be planarized, using, for example, a CMP operation, to yield a flat surface.

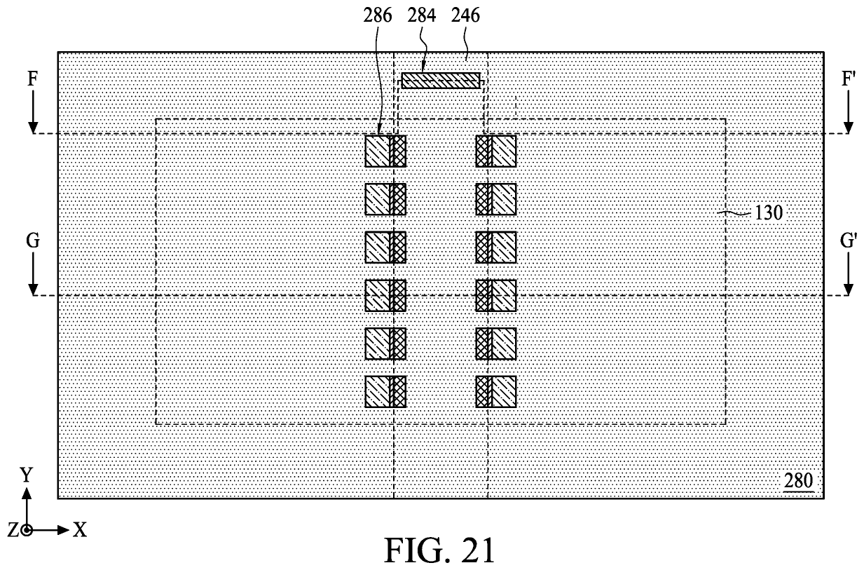

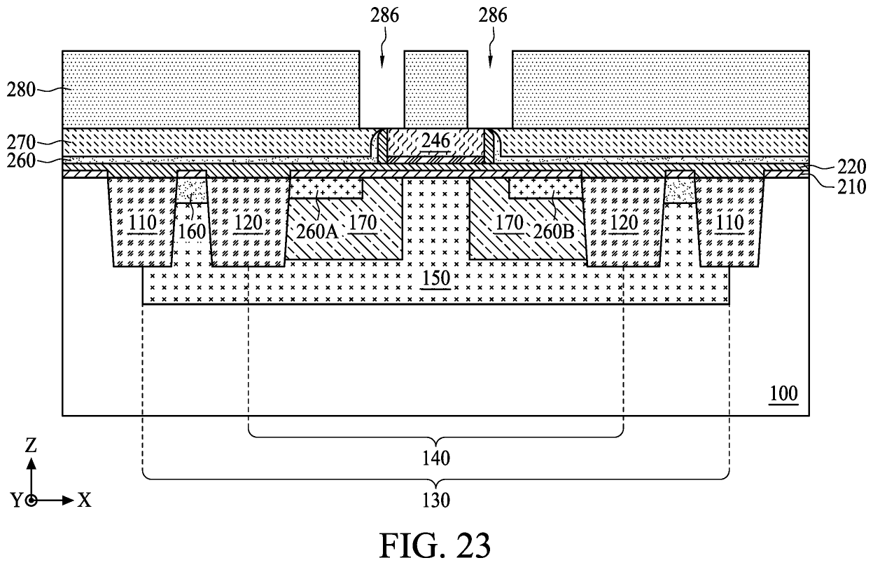

Referring to FIGS. 21 to 23, a first trench 284 and a plurality of second trenches 286 are formed through the second ILD layer 280 in accordance with step S524 in FIG. 7. In some embodiments, the first trench 284 is disposed outside the active area 130 to expose a portion of the gate electrode 246. The second trenches 286 are disposed inside the active area 130. In some embodiments, each second trench 286 exposes a portion of the gate electrode 246, a portion of the etch stop layer 260, and a portion of the first ILD layer 270. Referring to FIG. 23, each second trench 286 may overlap an area of the lightly-doped region 170 between the gate electrode 246 and the source region 260A or between the gate electrode 246 and the drain region 260B. In some embodiments, the first trench 284 and the second trenches 286 are simultaneously formed in at least one etching operation. The second ILD layer 280 may be etched using a dry etch, a wet etch, or a reactive-ion etching (RIE) operation, for example.

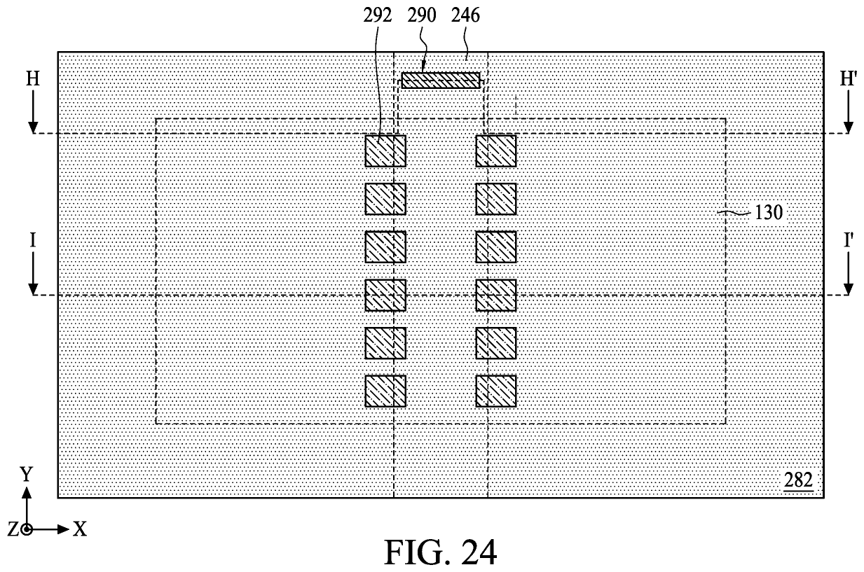

Referring to FIGS. 24 to 26, a first conductive material is deposited to fill the first trench 284 and the second trenches 286 in accordance with step S526 in FIG. 7. Accordingly, a first conductive contact 290 and a plurality of conductive plates 292 are formed. In some embodiments, the first conductive material is conformally and uniformly deposited on the second ILD layer 280 and in the first and second trenches 284 and 286 until the first and second trenches 284 and 286 are filled. The first conductive material includes polysilicon or metal, such as tungsten, or the like. The first conductive material may be formed using CVD, PVD, ALD or another suitable operation. A planarization process is performed to remove portions of the first conductive material above an upper surface 2802 of the second ILD layer 280. The excess conductive material may be removed from the second ILD layer 280 using, for example, a CMP operation.

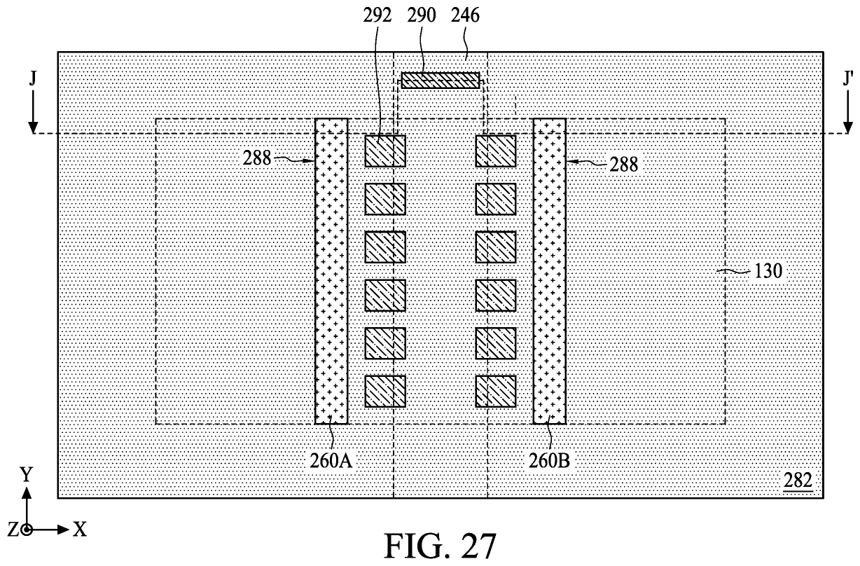

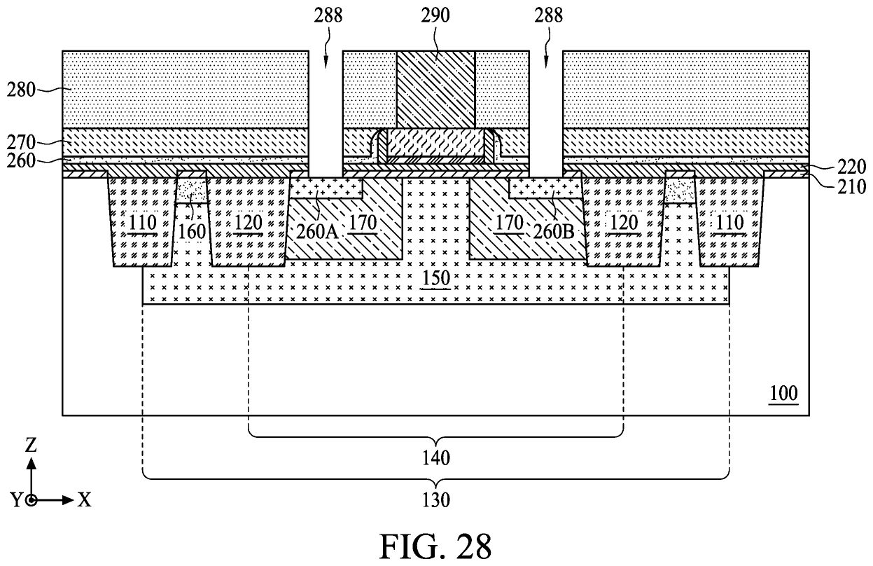

Referring to FIGS. 27 and 28, a pair of third trenches 288 are formed to expose the source region 260A and the drain region 260B in accordance with step S528 in FIG. 7. In some embodiments, the third trenches 288 penetrate, from top to bottom, the second ILD layer 280, the first ILD layer 270, the etch stop layer 260, the second dielectric layer 220, and the first dielectric layer 210. The third trenches 288 are formed using one or more etching operations.

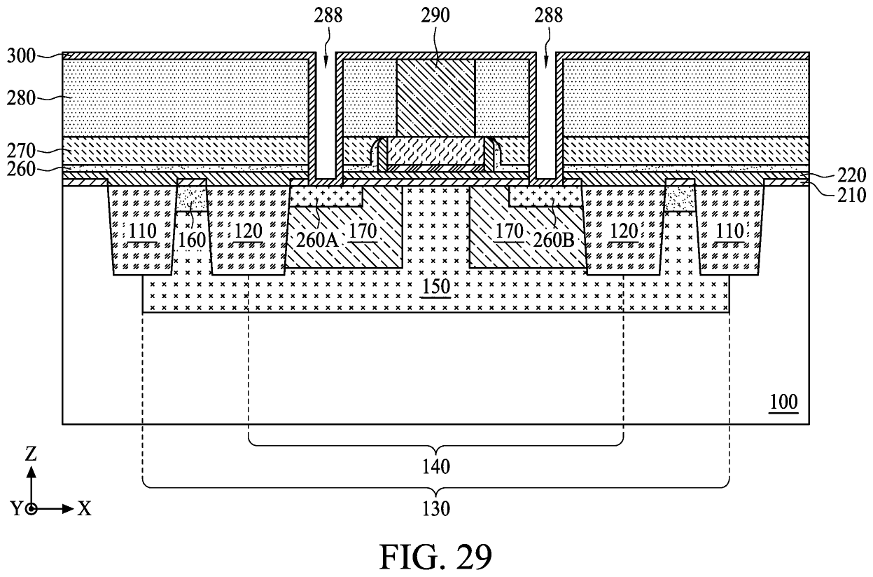

Referring to FIG. 29, a metal layer 300 is conformally deposited over the second ILD layer 280, over the first conductive contact 290, and in the third trenches 288. The metal layer 300 may include titanium (Ti), cobalt (Co), nickel (Ni), tantalum (Ta), or platinum (Pt). In some embodiments, PVD is used for forming the metal layer 300, although other methods, such as ALD, may also be used. In alternative embodiments, electroless plating, which can selectively form a metal layer on the source and drain regions 260A and 260B, but not on the second ILD layer 280 and the first conductive contact 290, is used for forming the metal layer 300.

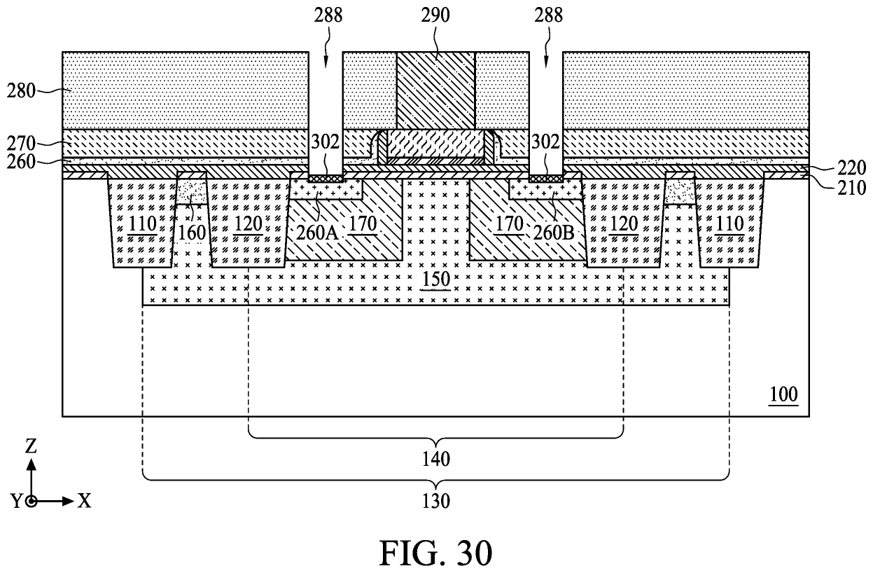

Referring to FIG. 30, an anneal operation is performed to react the metal layer 300 with silicon atoms in the silicon-containing substrate 100, thus forming a silicide layer 302 at the source and drain regions 260A and 260B (step S530). Portions of the metal layer 300 that have not reacted with the silicon substrate 100 are removed through an etching method such as a wet etching.

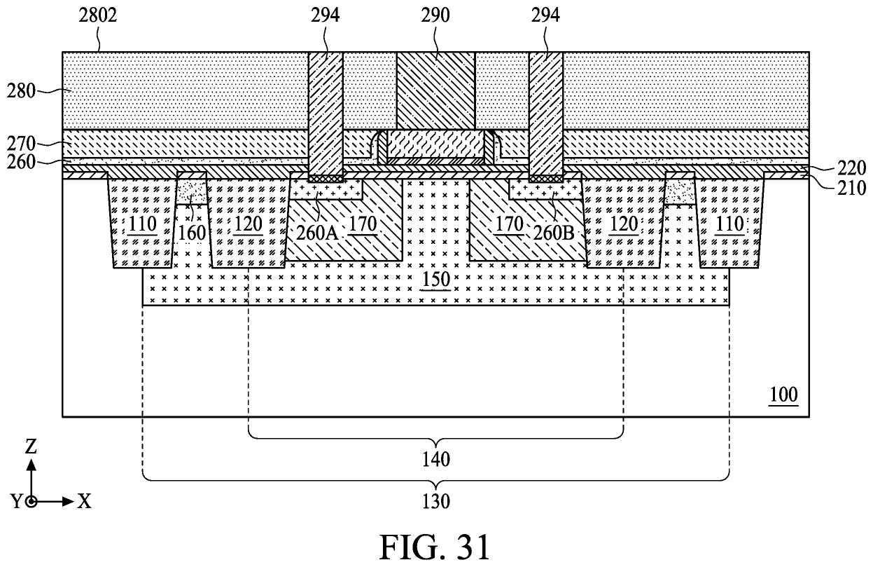

Referring to FIG. 31, a second conductive material is deposited to fill remaining portions of the third trenches 288 in accordance with step S532 in FIG. 7. Accordingly, a pair of second conductive contacts 294 are formed. After the deposition of the second conductive material, a CMP operation may be performed to planarize the upper surface 2802 of the second ILD layer 280. In some embodiments, the first conductive material and the second conductive material may be same or different.

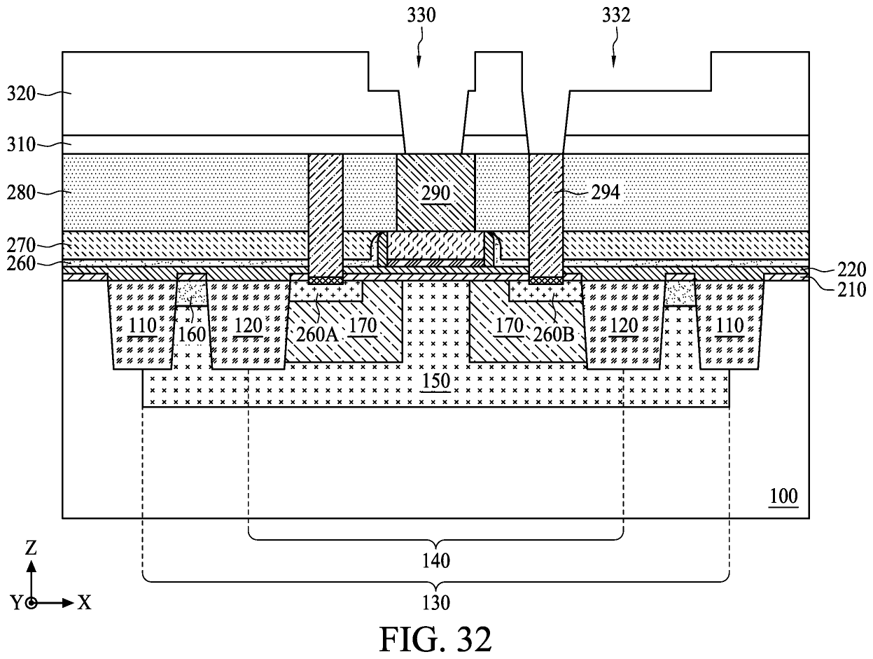

Referring to FIG. 32, an isolation layer 310 and a low-k dielectric layer 320 are subsequently formed on the second ILD layer 280, the first conductive contact 290, the conductive plates 292, and the second conductive contacts 294. The isolation layer 310 may act as an etch stop layer. In addition, the isolation layer 310 may act as a silicidation blocking layer (SBL) to reduce formation of excess silicide during subsequent formation of conductive contacts, which may be useful in reducing current leaked through a path provided by the excess silicide, thereby improving device performance. In some embodiments, the isolation layer 310 includes TEOS. The isolation layer 310 may be formed using CVD, plasma-enhanced CVD, sputter, or other suitable methods.

The isolation layer 310 and the low-k dielectric layer 320 have different dielectric materials. In some embodiments, the low-k dielectric layer 320 includes, for example, PSG, BSG, BPSG, USG, FSG, spin-on-polymers, silicon carbon material, or a combination thereof. The low-k dielectric layer 320 may be deposited by spin coating, CVD, or another suitable operation. In some embodiments, a planarizing process can be optionally performed after the deposition of the low-k dielectric layer 320 to yield an acceptably flat topology.

Subsequently, a third trench 330 and one or more fourth trenches 332 are formed to penetrate the isolation layer 310 and the low-k dielectric layer 320, wherein the first conductive contact 290 is exposed through the third trench 330 and one or more of the second conductive contacts are exposed through the fourth trenches 332.

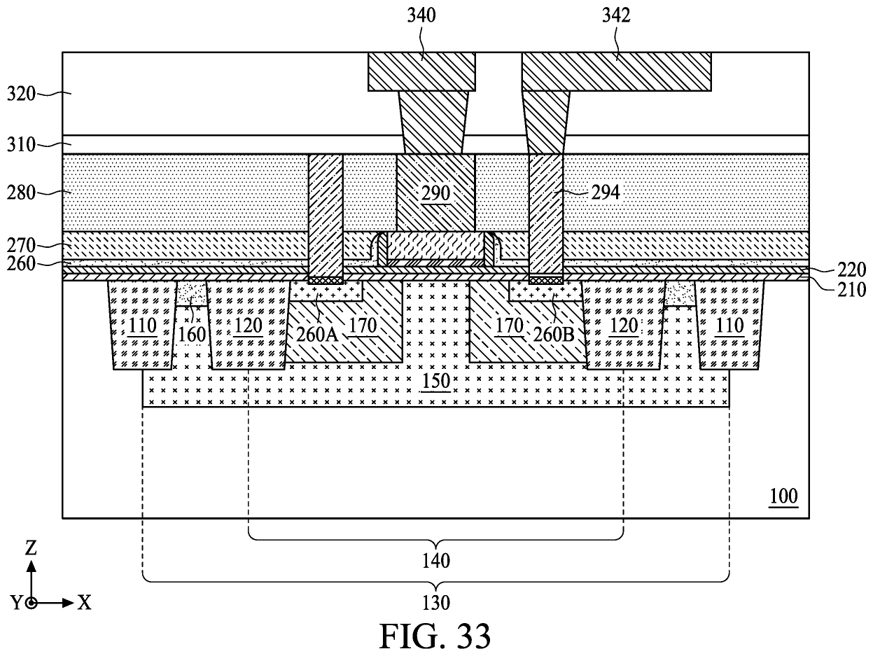

In accordance with step S534, a first interconnect structure 340 is formed to physically and electrically connect to the first conductive contact 290, and a second interconnect structure 342 is formed to physically and electrically connect to the second conductive contact 294, as illustrated in FIG. 33. The first interconnect structure 340 and the second interconnect structure 342 are formed by depositing a metal material in the third trench 330 and the fourth trenches 332. A planarization operation may be performed to remove excess portions of the metal material from a top surface of the low-k dielectric layer 320. As a result, top surfaces of the first interconnect structure 340 and the second interconnect structure 342 are coplanar with the top surface of the low-k dielectric layer 320. In some embodiments, the conductive plates 292 are electrically isolated from the first and second interconnect structures 340 and 342.

In accordance with some embodiments of the present disclosure, a method of fabricating a semiconductor device is provided. The method includes steps of forming a source region and a drain region in a substrate; forming a gate structure on the substrate, wherein the source region and the drain region are disposed on opposite sides of the gate structure and separated from the gate structure by a distance; depositing an inter-layer dielectric (ILD) layer over the substrate and the gate structure; forming a first trench in the ILD layer, wherein the first trench exposes a first portion of the gate structure and overlies an area between the gate structure and one of the source and drain regions from a top-view perspective; and depositing a first conductive material in the first trench to form a conductive plate, wherein the conductive plate is electrically connected to the gate structure.

In accordance with some embodiments of the present disclosure, a method of fabricating a semiconductor device is provided. The method includes steps of forming a source region and a drain region in the substrate; forming a gate structure on a substrate, wherein the gate structure extends in a first direction and has a length in a second direction different from the first direction, the source region and the drain region are disposed on opposite sides of the gate structure, and a distance between the source region and the drain region in the second direction is greater than the length of the gate structure; depositing an ILD layer to cover the substrate and the gate structure; forming a first conductive contact penetrating the ILD layer and connected to the gate structure; and forming a plurality of conductive plates penetrating the ILD layer and connected to the gate structure, wherein each conductive plate overlaps an area between the gate structure and one of the source and drain regions.

In accordance with some embodiments of the present disclosure, a semiconductor device is provided. The semiconductor device includes a substrate, a gate structure, a source region, a drain region, a pair of conductive plates, and a first conductive contact. The gate structure is disposed on a substrate and extends along a first direction, wherein the gate structure has a length in a second direction different from the first direction. The source region and the drain region are disposed in the substrate. The source and drain regions are separated from one another by a first distance greater than the length of the gate structure. The conductive plates are disposed over the gate structure, wherein each conductive plate extends in the second direction to overlap an area between the gate structure and the source region or the drain region. The first conductive contact is disposed on the gate structure. An electrical charge applied to the semiconductor device is conducted from the first conductive contact to the conductive plates through the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
forming a source region and a drain region in a substrate;
forming a gate structure on the substrate, wherein the source region and the drain region are disposed on opposite sides of the gate structure and separated from the gate structure by a distance;
depositing an inter-layer dielectric (ILD) layer over the substrate and the gate structure;
forming a first trench in the ILD layer, wherein the first trench exposes a first portion of the gate structure and overlies an area between the gate structure and one of the source and drain regions from a top-view perspective; and
depositing a first conductive material in the first trench to form a conductive plate, wherein the conductive plate is electrically connected to the gate structure.

2. The method of claim 1, further comprising:
forming a second trench penetrating the ILD layer to expose a second portion of the gate structure, wherein the first trench and the second trench are formed using a same process; and
depositing the first conductive material in the second trench to form a first conductive contact.

3. The method of claim 2, further comprising:
forming a plurality of first isolation structures in the substrate to define an active region, wherein the first conductive contact is outside the active region, and the conductive plate overlaps the active region from a top-view perspective.

4. The method of claim 3, further comprising:
forming a pair of guard regions in the active region and on opposite sides of the source and drain regions,
wherein the guard region has a first conductivity type and the source and drain regions has a second conductivity type different from the first conductivity type.

5. The method of claim 2, further comprising:
forming a plurality of third trenches penetrating the ILD layer to expose the source region and the drain region;
depositing a metal layer in the third trenches and onto the source region and the drain region;
performing an annealing operation to react the metal layer with the source region and the drain region to form a silicide layer in the third trenches; and
depositing a second conductive material in the third trenches over the silicide layer to form a second conductive contact.

6. The method of claim 5, further comprising, prior to the formation of the gate structure:
forming a first dielectric layer on the substrate; and
depositing a second dielectric layer on the first dielectric layer;
wherein the third trenches penetrate the first and second dielectric layers, and the first dielectric layer comprises material provided by the substrate.

7. The method of claim 5, further comprising:
forming a first interconnect structure over the ILD layer, wherein the first interconnect structure is physically and electrically coupled to the first conductive contact; and
depositing a third dielectric layer on the ILD layer to laterally surround the first interconnect structure and cover the conductive plate.

8. The method of claim 1, wherein from a top-view perspective, the conductive plate extends from the gate structure toward the source or drain region to overlap an area between the gate structure and the source or drain region.

9. The method of claim 1, wherein the distance is in a range of about 40 nm to about 50 nm.

10. A method of fabricating a semiconductor device, comprising:
forming a source region and a drain region in a substrate;
forming a gate structure on the substrate, wherein the gate structure extends in a first direction and has a length in a second direction different from the first direction, the source region and the drain region are disposed on opposite sides of the gate structure, and a distance between the source region and the drain region in the second direction is greater than the length of the gate structure;
depositing an ILD layer to cover the substrate and the gate structure;
forming a first conductive contact penetrating the ILD layer and connected to the gate structure; and
forming a plurality of conductive plates penetrating the ILD layer and connected to the gate structure, wherein each conductive plate overlaps an area between the gate structure and one of the source and drain regions.

11. The method of claim 10, wherein the first conductive contact and the conductive plates are simultaneously formed.

12. The method of claim 10, wherein the conductive plates are symmetric about a central axis of the gate structure, and the central axis is parallel to the first direction.

13. The method of claim 10, wherein the plurality of conductive plates extend toward one of the source region and the drain region and are evenly spaced in the first direction.

14. The method of claim 10, further comprising forming a plurality of second conductive contacts penetrating the ILD layer and connected to the source region and the drain region.

15. The method of claim 14, further comprising forming a first interconnect structure and a second interconnect structure over the ILD layer, the first conductive contact, the second conductive contacts, and the conductive plates, wherein the first interconnect structure is physically connected to the first conductive contact, and the second interconnect structure is physically connected to the second conductive contacts.

16. The method of claim 14, further comprising forming a metal silicide layer on the source region and the drain region prior to the formation of the second conductive contacts.

17. The method of claim 10, wherein a difference between the length of the gate structure and a distance between the source region and the drain region is in a range of about 80 nm to about 100 nm.

18. A semiconductor device, comprising:
a gate structure disposed on a substrate and extending along a first direction, wherein the gate structure has a length in a second direction different from the first direction;
a source region disposed in the substrate on a first side of the gate structure;
a drain region disposed in the substrate on a second side of the gate structure opposite to the first side, wherein the source region are separated from the drain region by a first distance in the second direction and the first distance is greater than the length of the gate structure; and
a pair of conductive plates disposed over and electrically connected to the gate structure, wherein each of the conductive plates extends in the second direction and overlaps an area between the gate structure and the source region or an area between the gate structure and the drain region.

19. The semiconductor device of claim 18, wherein the conductive plates are separated from each other by a second distance less than the length of the gate structure.

20. The semiconductor device of claim 18, further comprising a first conductive contact disposed on the gate structure, wherein the first conductive contact and the conductive plates have a same height in a third direction different from the first and second directions.
